(19) United States
(12) Patent Application Publication
(10) Pub. No.: US 2011/0080722 A1
(43) Pub. Date: Apr. 7, 2011

(54) DISPLAY APPARATUS

(75) Inventors: Masaki ISHIKAWA, Kawasaki (JP); Akira Saito, Kawasaki (JP)

(73) Assignee: FUJITSU LIMITED, Kawasaki (JP)

(21) Appl. No.: 12/698,459

(22) Filed: Feb. 2, 2010

(30) Foreign Application Priority Data
Oct. 3, 2009 (JP) 2009-057188

(51) Int. Cl. H05K 7/00

(52) U.S. Cl. 361/829

(57) ABSTRACT

A display apparatus includes a display unit, a frame that covers a side part of the display unit, a supporting plate disposed on a back face side of the display unit, and a connecting component that connects the frame and the supporting plate. The frame includes an engaged section provided inside the frame. The connecting component includes a base section located in a position closer to the back face side of the display unit than the supporting plate, a limb section that extends from the base section into a space between the side part of the display unit and the frame, and an engaging section that extends from the limb section and defines a position of the frame in a direction of a depth of the display unit by engaging the engaged section.

### CROSS-REFERENCE TO RELATED APPLICATIONS

This application is based upon and claims the benefit of priority from the prior Japanese Patent Application No. 2009-57188 filed on Mar. 10, 2009, the entire contents of which are incorporated herein by reference.

### BACKGROUND

1. Field

Embodiments described below relate to a display apparatus and method of manufacturing of same.

2. Description of the Related Art

A typical display apparatus is generally provided with a display unit and a frame covering an edge of the display unit. For example, Japanese Laid-open Patent Publication No. 2001-83900 and Japanese Laid-open Patent Publication No. 2003-295788 discuss a technique related to a typical display apparatus. As other related art documents, Japanese Laid-open Patent Publication No. 10-246881, for example, is directed to a typical display.

### SUMMARY

A display apparatus includes a display unit, a frame that covers a side part of the display unit, a supporting plate disposed on a back face side of the display unit, and a connecting component that connects the frame and the supporting plate. The frame includes an engaged section provided inside the frame. The connecting component includes a base section located in a position closer to the back face side of the display unit than the supporting plate, a limb section that extends from the base section into a space between the side part of the display unit and the frame, and an engaging section that extends from the limb section and defines a position of the frame in a direction of a depth of the display unit by engaging the engaged section.

Additional aspects and/or advantages will be set forth in part in the description which follows and, in part, will be apparent from the description, or may be learned by practice of the invention.

The above-described embodiments of the present invention are intended as examples, and all embodiments of the present invention are not limited to including the features described above.

### BRIEF DESCRIPTION OF THE DRAWINGS

These and/or other aspects and advantages will become apparent and more readily appreciated from the following description of the embodiments, taken in conjunction with the accompanying drawings of which:

FIGS. 1A and 1B illustrate external views of a display apparatus;

FIG. 2 illustrates an exploded perspective view of a display apparatus;

FIG. 3 illustrates a back view of a display apparatus in a state in which a supporting plate is removed therefrom;

FIGS. 4A, 4B, 4C and 4D depict various illustrations of a bracket;

FIGS. 5A, 5B and 5C depict various illustrations of a bracket;

FIG. 6 depicts a supporting plate;

FIGS. 7A, 7B and 7C depict various illustrations of a supporting plate;

FIGS. 8A and 8B depict various illustrations of a movable body and a fixed body;

FIG. 9 is a sectional view of a display apparatus;

FIGS. 10A and 10B illustrate an enlarged sectional view of a display apparatus;

FIGS. 11A and 11B depict various illustrations of a connecting component;

FIGS. 12A, 12B and 12C depict various illustrations of a connecting component;

FIGS. 13A and 13B illustrate an explanatory diagram of an engagement between an engaging section and an engaged section;

FIGS. 14A and 14B illustrate an explanatory diagram of a pedestal section;

FIGS. 15A, 15B and 15C illustrate an explanatory diagram of maintenance; and

FIGS. 16A, 16B and 16C illustrate an explanatory diagram of maintenance.

### DETAILED DESCRIPTION OF THE PREFERRED EMBODIMENTS

Reference will now be made in detail to the embodiments, examples of which are illustrated in the accompanying drawings, wherein like reference numerals refer to the like elements throughout. The embodiments are described below to explain the present invention by referring to the figures.

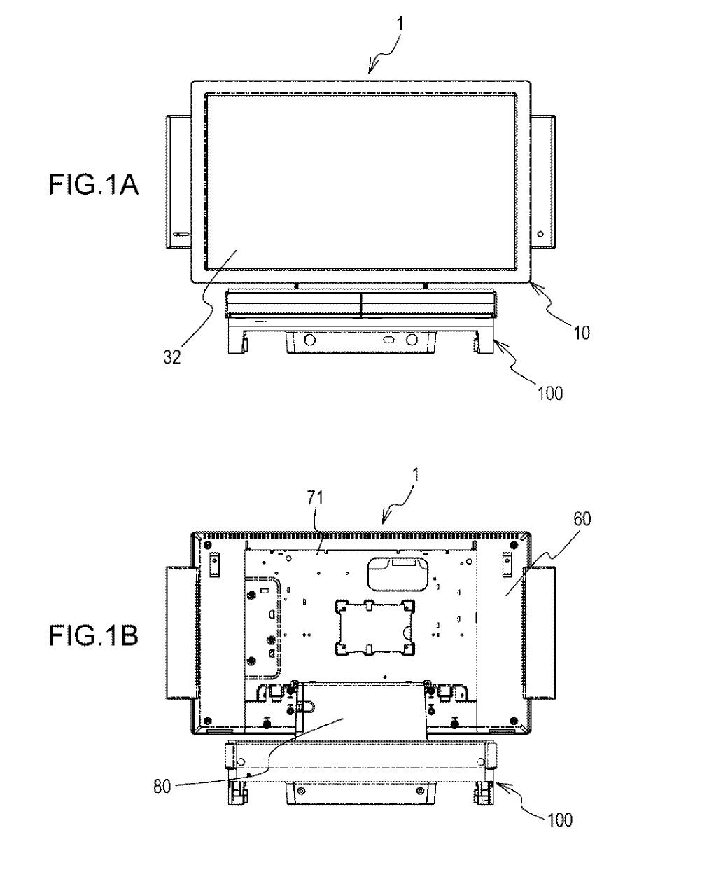

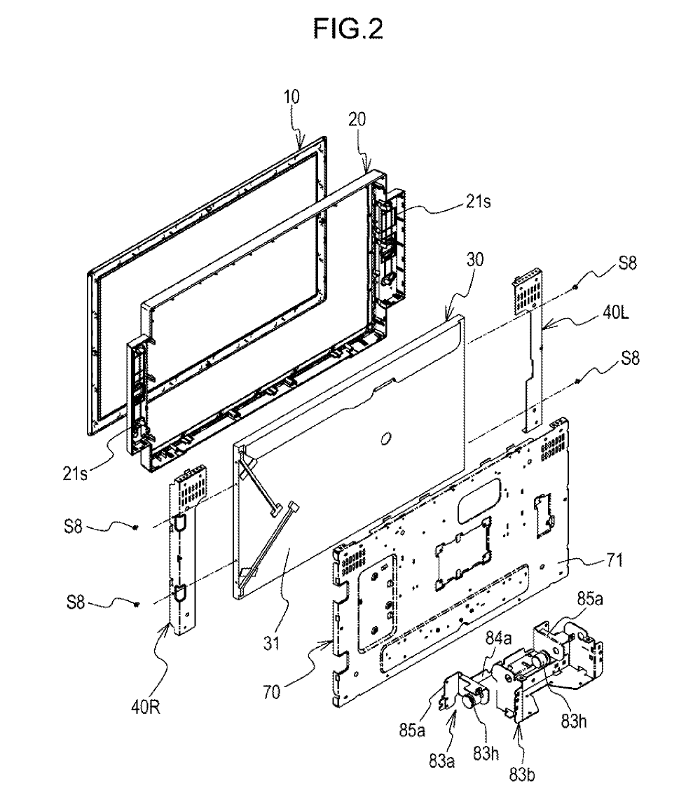

FIGS. 1A and 1B are each an external view of a display apparatus 1. FIG. 2 is an exploded perspective view of the display apparatus 1. Incidentally, in FIG. 2, some of the parts of the display apparatus 1 are not shown. The display apparatus 1 includes a display unit 30 (FIG. 2), a pedestal section 80, and a main body section 100. The display unit 30 has, on a front side thereof, a display screen 32 for displaying data including an image. The pedestal section 80 is provided on the main body section 100. The pedestal section 80 makes it possible to adjust the angle of the display unit 30 with respect to the main body section 100. The main body section 100 incorporates a mechanism for reading a storage medium.

As shown in FIG. 2, a front panel 10 is attached to a front edge part of the display unit 30. Moreover, a frame 20 is attached to a side face of the display unit 30. The front panel 10 and the frame 20 may be made of synthetic resin. The front panel 10 and the frame 20 are assembled together. The front panel 10 and the frame 20 have a virtually rectangular shape. The frame 20 has, at both sides thereof, housing sections 21s for housing components including speakers. The frame 20 covers (surrounds or encloses) a side face of the display unit 30.

On both sides on a back face 31 of the display unit 30, brackets 40L and 40R are attached. The brackets 40L and 40R are fixed on both side faces of the display unit 30 with screws s8. Moreover, a supporting plate 70 is attached to the back face 31 of the display unit 30 to which the brackets 40L and 40R are attached. The brackets 40L and 40R and the supporting plate 70 may be made of metal. Furthermore, as shown in FIG. 1B, a back panel 60 is fixed on a back face 71 side of the supporting plate 70. The back panel 60 is made of synthetic resin.

As shown in FIG. 2, a movable body 83a and a fixed body 83b are provided in the pedestal section 80. The movable body 83a and the fixed body 83b are rotatably connected to each other by a pair of hinge mechanisms 83h. The fixed body 83b is fixed to the main body section 100. The movable body 83a is fixed to the back face 71 of the supporting plate 70. The movable body 83a has a pair of holding pieces 85a fixed to the back face 71 and a connecting piece 84a connecting the pair of holding pieces 85a.

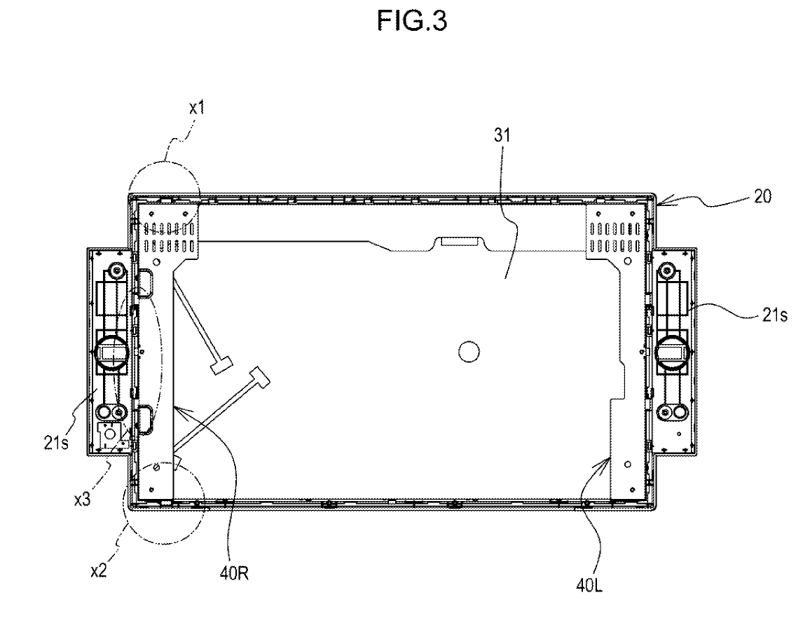

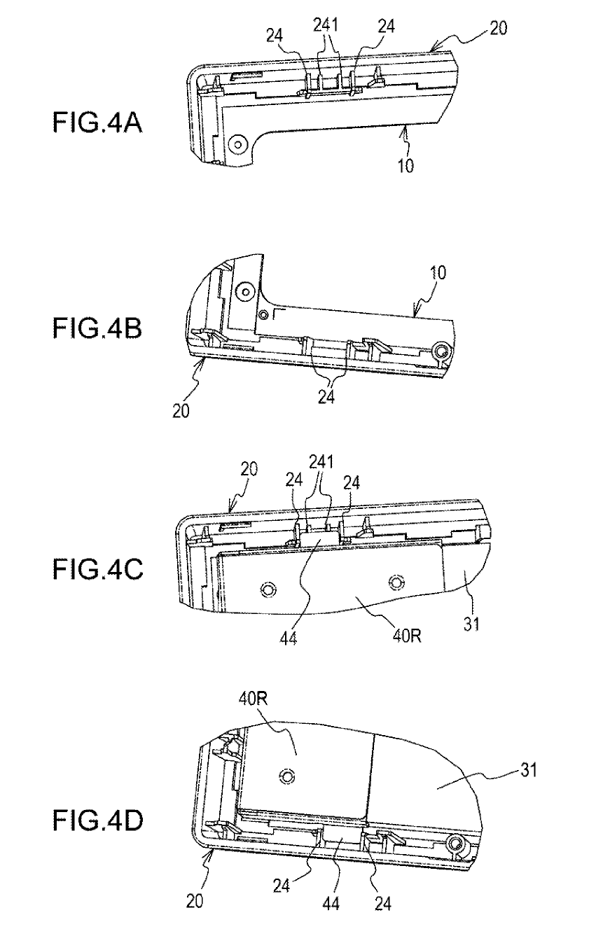

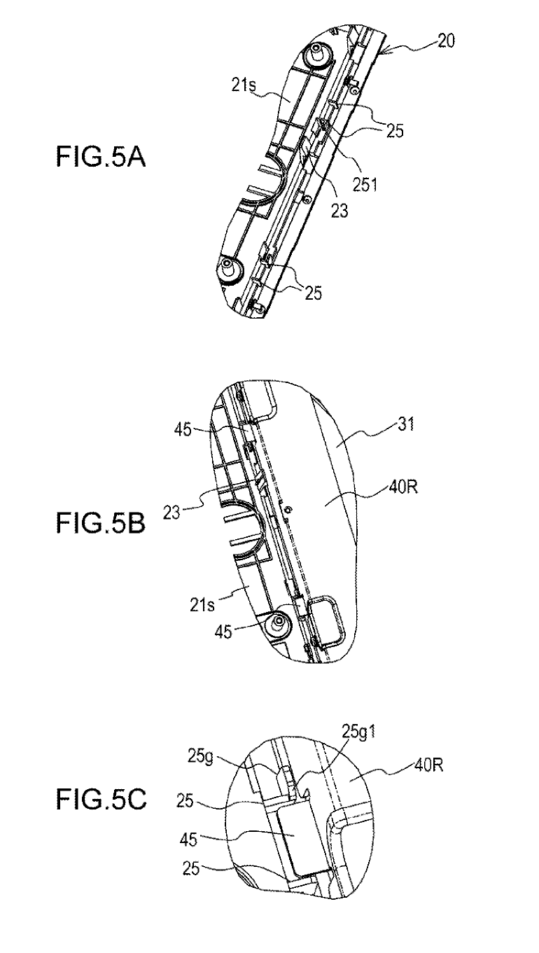

The brackets 40L and 40R will be described. FIG. 3 is a back view of the display apparatus 1 in a state in which the supporting plate 70 is removed therefrom. Incidentally, FIG. 3 shows a state in which the speakers are removed. FIGS. 4A, 4B, 4C and 4D and FIGS. 5A , 5B and 5C depict the bracket 40R. FIGS. 4A and 4C are each an enlarged view of a portion surrounded by a dashed line x1 in FIG. 3. FIGS. 4B and 4D are each an enlarged view of a portion surrounded by a dashed line x2 in FIG. 3. FIGS. 4A and 4B show the front panel 10 and the frame 20 in a state in which the display unit 30 and the bracket 40R are removed therefrom. FIGS. 4C and 4D show a state in which the display unit 30 and the bracket 40R are attached to the front panel 10 and the frame 20.

As shown in FIGS. 4A and 4B, pairs of ribs 24 are provided on an inner face of the frame 20 on a longer side(s) thereof. Incidentally, as shown in FIG. 4A, strengthening ribs 241 for strengthening (or supporting) the ribs 24 are provided between the upper ribs 24. As shown in FIGS. 4C and 4D, a convex piece 44 engages the ribs 24 in such a way that the convex piece 44 is sandwiched between the ribs 24. The convex piece 44 is provided at the upper and lower ends of the bracket 40R. The convex pieces 44 project in a planar direction of the display unit 30, that is, project upward and downward. When the convex pieces 44 engage the pairs of ribs 24, displacement in a direction perpendicular to the direction in which the convex pieces 44 project, that is, displacement in a lateral direction is narrowed, whereby displacement of the frame 20 with respect to the bracket 40R in a lateral direction is narrowed. Since the bracket 40R is attached to the display unit 30, displacement of the frame 20 with respect to the display unit 30 in a lateral direction is narrowed. Moreover, in a state in which the ribs 24 and the convex pieces 44 engage, a position of the frame 20 with respect to the bracket 40R in a vertical direction is not narrowed. That is, a fixed clearance is kept between the convex piece 44 and an upper side of the frame 20. Incidentally, the bracket 40L has the same structure as the bracket 40R. The convex piece 44 is an example of a convex section. The pair of ribs 24 is an example of a concave section into which the convex section is inserted.

FIGS. 5A and 5B are each an enlarged view of a portion surrounded by a dashed line x3 in FIG. 3. FIG. 5A shows the front panel 10 and the frame 20 in a state in which the display unit 30 is removed therefrom. FIG. 5B shows a state in which the display unit 30 is attached to the front panel 10 and the frame 20. As shown in FIG. 5A, a plurality of pairs of ribs 25 are provided inside the frame 20 on the shorter side thereof. Incidentally, a rib 251 for strengthening the rib 25 is provided for some ribs 25. Moreover, a plurality of locking pieces 23 are provided inside the frame 20 on the shorter side thereof. The locking pieces 23 engage the edge of the supporting plate 70. As shown in FIG. 5B, a plurality of convex pieces 45 projecting leftward are provided in the bracket 40R. When the convex pieces 45 engage the pairs of ribs 25, displacement in a direction perpendicular to a direction in which the convex pieces 45 project, that is, displacement in a vertical direction is narrowed, whereby displacement of the frame 20 with respect to the bracket 40R in a vertical direction is narrowed. As a result, displacement of the frame 20 with respect to the display unit 30 in a vertical direction is narrowed. Furthermore, in a state in which the ribs 25 and the convex pieces 45 engage, the position of the frame 20 with respect to the bracket 40R in a lateral direction is not narrowed. A fixed clearance is kept between the convex pieces 45 and a side of the frame 20. The convex piece 45 is an example of a convex section. The pair of ribs 25 is an example of a concave section into which the convex section is inserted.

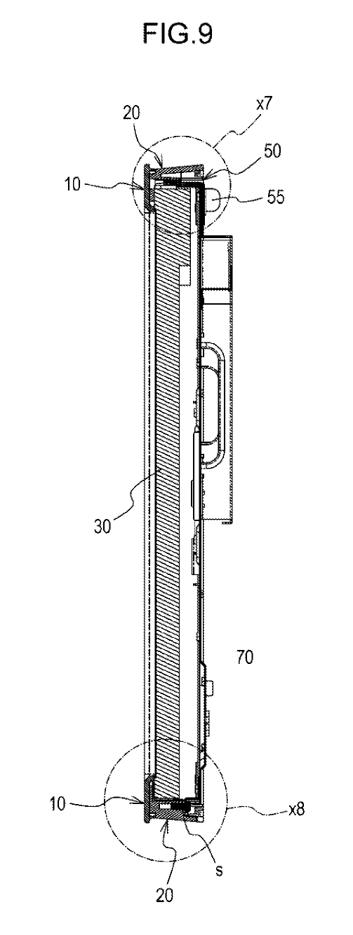

FIG. 5C is an enlarged view of a portion around the convex piece 45. A guide rib 25g is provided in the rib 25. The guide rib 25g is perpendicular to one rib 25. The rib 25 and the guide rib 25g are integrally provided. The guide rib 25g has a guide face 25g1 for guiding a grasped piece 55 (FIG. 9) between the pair of ribs 25. As described above, when the convex pieces 44 engage the pairs of ribs 24 and the convex pieces 45 engage the pairs of ribs 25, the position of the frame 20 with respect to the display unit 30 is defined. The brackets 40R and 40L are examples of a positioning component.

Such positioning can also be achieved by providing the frame 20 or the front panel 10 with a pin projecting in a direction of a depth of the display unit 30. As a result of a fit of this pin, the position of the frame 20 or the front panel 10 with respect to the display unit 30 is defined and the position of the display unit 30 is enabled to be selectively adjusted. However, when such a pin projecting in the depth direction is provided, the frame 20 cannot be formed as a narrow frame. This embodiment makes it possible to form the frame 20 as a narrow frame by performing positioning with the convex pieces 44 and 45 projecting in a planar direction.

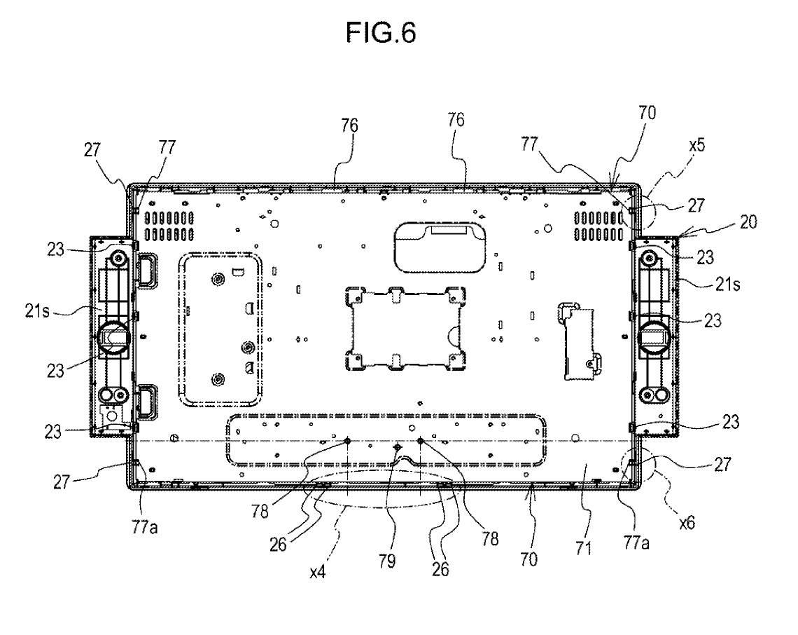

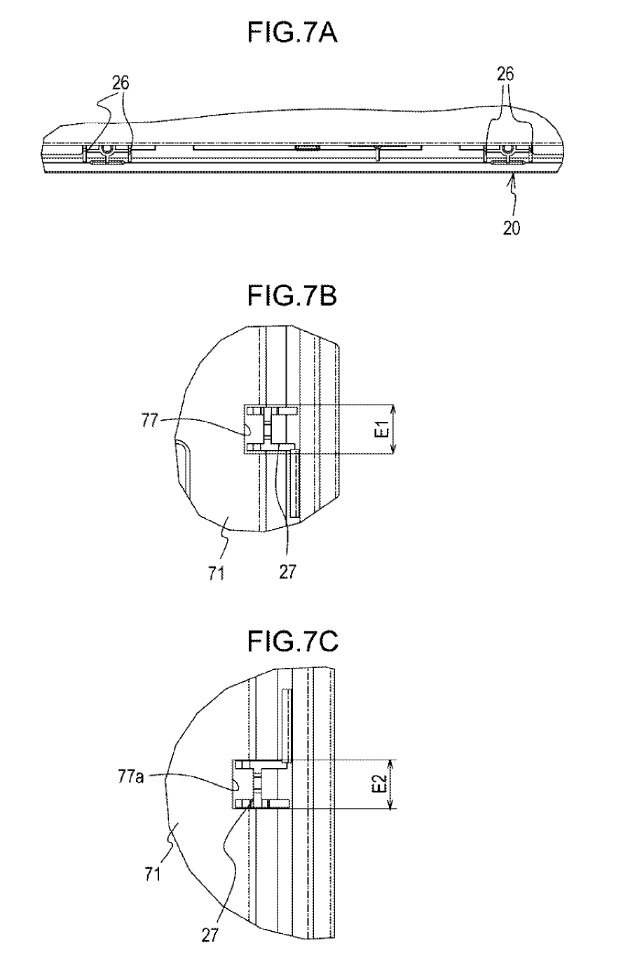

The supporting plate 70 will be described. FIG. 6 and FIGS. 7A, 7B and 7C depict the supporting plate 70. FIG. 6 is a back view of the display apparatus 1 in a state in which the back panel 60 and a connecting component 50, which are described in detail below, are removed therefrom. As shown in FIG. 6, a plurality of convex pieces 76 are provided on longer side(s) of the supporting plate 70. Incidentally, in FIG. 6, the convex pieces 76 provided on the lower longer side of the supporting plate 70 are not shown in the drawing. Of the convex pieces 76, the convex pieces 76 provided on the upper longer side project upward, and the convex pieces 76 provided on the lower longer side project downward. Moreover, concave sections 77 and 77a are provided on the shorter sides of the supporting plate 70 in an upper part and a lower part thereof, respectively.

FIG. 7A is an enlarged view of a portion surrounded by a dashed line x4 in FIG. 6. As shown in FIG. 7A, pair of ribs 26 in which the convex pieces 76 engage are provided inside the frame 20. When the convex pieces 76 and the pairs of ribs 26 engage, the position of the frame 20 with respect to the supporting plate 70 in a lateral direction is defined. Moreover, in a state in which the convex pieces 76 and the ribs 26 engage, the position of the frame 20 with respect to the supporting plate 70 in a vertical direction is not narrowed. That is, a fixed clearance is set between the tips of the convex pieces 76 and an inner face of the frame 20. The convex piece 76 is an example of a convex section. The pair of ribs 26 is an example of a concave section into which the convex section is inserted.

FIG. 7B is an enlarged view of a portion surrounded by a dashed line x5 in FIG. 6. FIG. 7C is an enlarged view of a portion surrounded by a dashed line x6 in FIG. 6. As shown in FIGS. 7B and 7C, convex sections 27 engaging the concave sections 77 and 77a are provided inside the frame 20. The width E2 of the concave section 77a is smaller than the width E1 of the concave section 77. Therefore, the position of the frame 20 with respect to the supporting plate 70 in a vertical direction is defined primarily by the engagement between the concave section 77a and the convex section 27. In this way, the position of the frame 20 with respect to the supporting plate 70 is defined. The convex section 27 is an example of a convex section. The concave sections 77 and 77a are examples of a concave section into which the convex section is inserted.

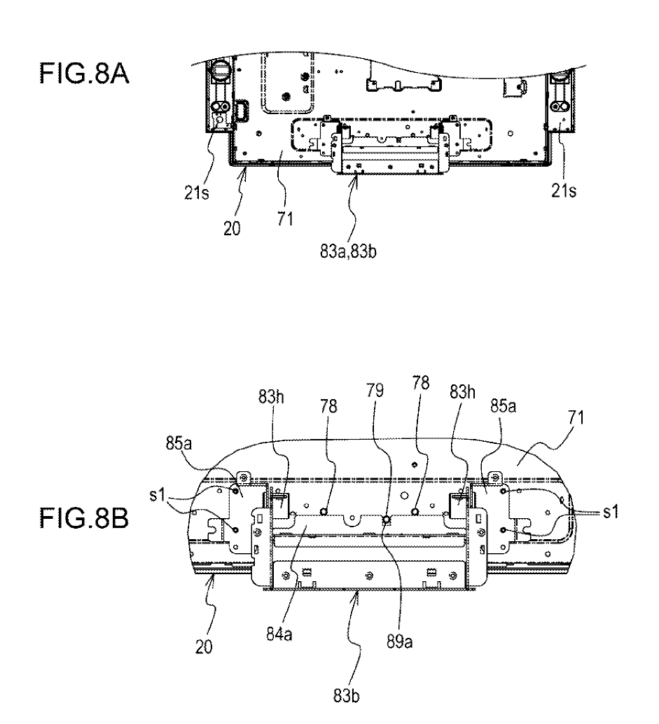

The movable body 83a and the fixed body 83b will be described. FIGS. 8A and 8B each show the movable body 83a and the fixed body 83b. FIG. 8A is a back view showing a part of the display apparatus 1 in a state in which the back panel 60 is removed therefrom and a cover covering the movable body 83a and the fixed body 83b is removed. FIG. 8B is an enlarged view of the movable body 83a and the fixed body 83b. When the connecting piece 84a of the movable body 83a abuts burring holes 78 and 79 provided on the back face 71 side of the supporting plate 70, the position of the supporting plate 70 with respect to the movable body 83a is defined. Moreover, as shown in FIG. 8B, the two burring holes 78 are provided so as to be arranged side by side in a horizontal direction. The burring hole 79 is provided in a position located somewhat (relatively) below the two burring holes 78. The connecting piece 84a has a notch section 89a engaging the burring hole 79. The notch section 89a has a concave shape. When the two burring holes 78 abut the movable body 83a, the position of the supporting plate 70 with respect to the movable body 83a in a vertical direction is defined. Moreover, when the burring hole 79 fits into the notch section 89a, the position of the supporting plate 70 with respect to the movable body 83a in a lateral direction is defined. In this way, the position of the supporting plate 70 with respect to the movable body 83a is defined with a high degree of accuracy. This makes it possible to prevent the display unit 30 from being attached obliquely with respect to the horizontal direction.

Furthermore, as shown in FIG. 6, the burring holes 78 and 79 are provided in positions sandwiched between the two pairs of ribs 26. In other words, the two pairs of ribs 26 are provided in positions near the burring holes 78 and 79, and define the position of the frame 20 with respect to the supporting plate 70 in a lateral direction in positions near the burring holes 78 and 79 which become a factor defining the inclination of the supporting plate 70 with respect to the pedestal section 80. In this way, the inclination of the frame 20 is controlled.

Moreover, as shown in FIG. 6, a position in which the convex section 27 and the concave section 77a engage is located below the burring holes 78 and 79. By defining the position of the frame 20 with respect to the supporting plate 70 in a vertical direction in a position near the burring holes 78 and 79, the inclination of the frame 20 is controlled.

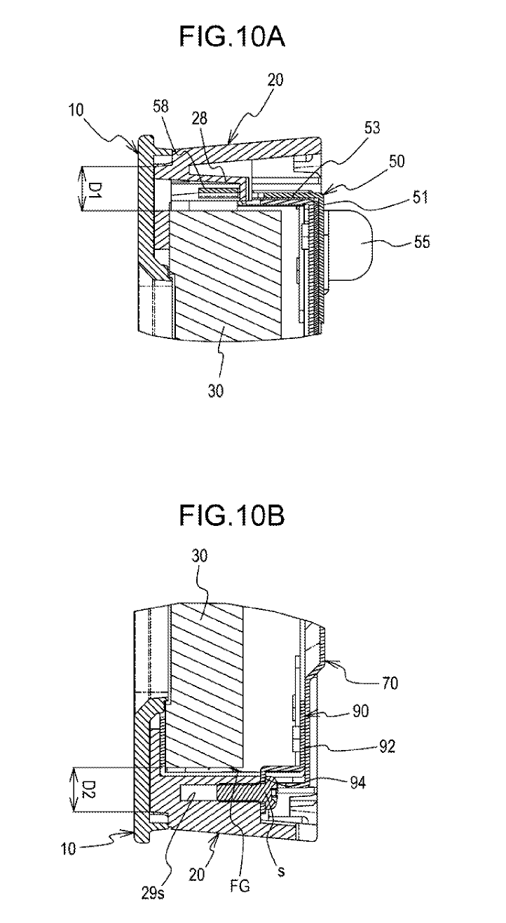

FIG. 9 is a sectional view of the display apparatus 1. As shown in FIG. 9, the connecting component 50 is attached in an upper part of the display apparatus 1. In FIG. 9, a left side of the drawing corresponds to a front side of the display apparatus 1. FIGS. 10A and 10B are enlarged views of portions surrounded by a dashed line x7 and a dashed line x8, respectively, in FIG. 9. As shown in FIG. 10A, the connecting component 50 is virtually L-shaped in cross section, and is made of metal. The connecting component 50 has the function of connecting the inside of an upper part of the frame 20 and the supporting plate 70. Specifically, when an engaging section 58 provided in the connecting component 50 engages an engaged section 28 provided in the frame 20, the frame 20 and the connecting component 50 are connected. This makes it possible to reduce a distance D1 between an upper end face of the display unit 30 and an inner side face of the frame 20, and form the frame 20 as a narrow frame.

As shown in FIG. 10B, a holding component 90 surrounds a side of a lower part of the display unit 30. The holding component 90 is virtually U-shaped in cross section, and is made of metal. The holding component 90 is fixed to the frame 20 with a screw s. Moreover, the supporting plate 70 is attached to the holding component 90 with an unillustrated screw. The holding component 90 includes a holding section 92 and a projecting piece 94 extending downward from the holding section 92. A flat spring FG for grounding the display unit 30 is attached to the inside of the holding section 92. The projecting piece 94 has a hole through which the screw s is placed. The frame 20 has a screw hole 29s in a position corresponding to a hole provided in the projecting piece 94. As shown in FIG. 10B, the holding component 90 is virtually U-shaped in cross section. This makes it possible to reduce a distance D2 between a lower end face of the display unit 30 and an inner side face of the frame 20, and form the frame 20 as a narrow frame. For example, when the above-described connecting component 50 or holding component 90 is virtually Z-shaped in cross section, the thickness of the frame in a planar direction thereof is increased, making it impossible to form the frame as a narrow frame.

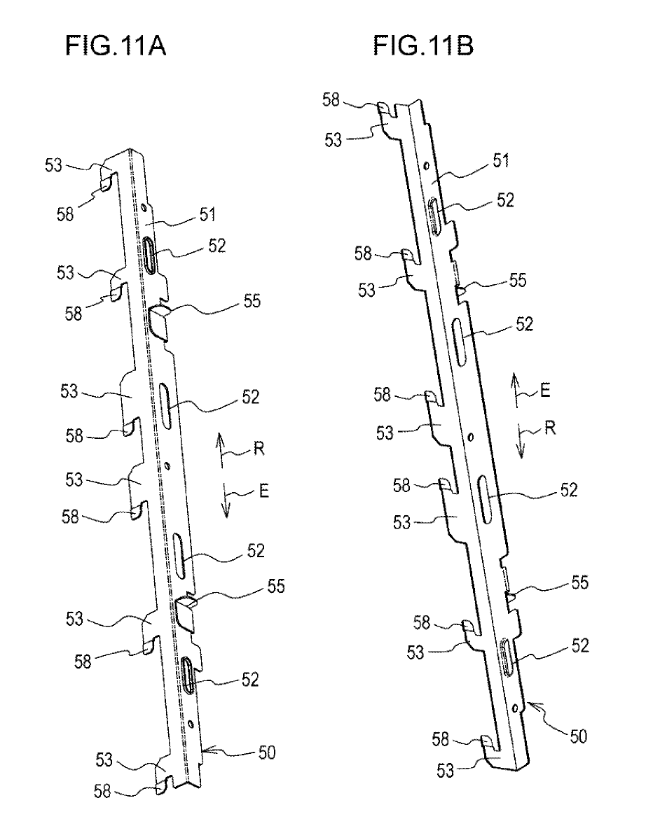

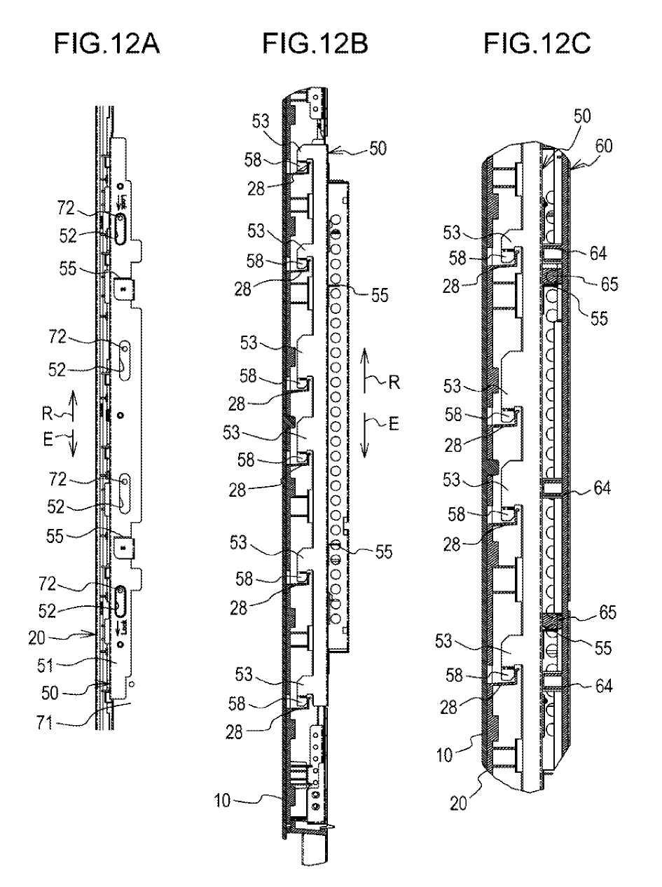

FIGS. 11A and 11B and FIGS. 12A, 12B and 12C depict the connecting component 50. FIGS. 11A and 11B are each a perspective view of the connecting component 50. The connecting component 50 includes a base section 51, a limb section 53 extending from the base section 51 in a direction nearly perpendicular to the base section 51, and an engaging section 58 extending from the limb section 53. A plurality of limb sections 53 extend from the base section 51. The engaging section 58 engages the engaged section 28 of the frame 20. Moreover, the base section 51 has two grasped pieces 55. Furthermore, the base section 51 has a plurality of guide holes 52 extending in a longitudinal direction.

FIG. 12A shows the connecting component 50 as seen from the back face side of the display apparatus 1. As shown in FIG. 12A, the connecting component 50 is disposed along the longer side of the supporting plate 70 in the upper part thereof. The base section 51 is located in a position closer to the back face than the supporting plate 70. The limb section 53 is placed in a space between the side face of the display unit 30 and the frame 20. When the connecting component 50 is slid in a release direction R along the longer side of the supporting plate 70, the engagement of the connecting component 50 with the engaged section 28, which will be described later, is released. Incidentally, when the connecting component 50 is slid in an engaging direction E at the time of assembly of the connecting component 50, the connecting component 50 engages the engaged section 28. In a state shown in FIG. 12A, the engaged section 28 and the connecting component 50 engage. The base section 51 overlaps the back face 71 of the supporting plate 70. The back face 71 has guide pins 72. The guide pins 72 and the guide holes 52 have the function of guiding the siding of the connecting component 50.

FIG. 12B is a sectional view showing a state in which the engaging section 58 and the engaged section 28 engage. In FIG. 12B, a left side of the drawing corresponds to a front side of the display apparatus 1. As shown in FIG. 12B, a plurality of engaged sections 28 are provided inside the frame 20 so as to correspond to a plurality of engaging sections 58. When the connecting component 50 is slid in a release direction R in this state, the engaging section 58 is removed from engagement with the engaged section 28, whereby the engagement of the engaging section 58 with the engaged section 28 is released. As a result, the connecting component 50 is removed. Moreover, since the base section 51 is located on the back face 71 side of the supporting plate 70, when the engaging section 58 engages the engaged section 28, the base section 51 is fixed to the back face 71 of the supporting plate 70. In this way, the connecting component 50 connects the frame 20 and the supporting plate 70.

FIG. 12C is a sectional view showing a state in which the back panel 60 is attached when the frame 20 and the supporting plate 70 are in a state in which they are connected by the connecting component 50. As shown in FIG. 12C, on that face of the back panel 60 where the back panel 60 faces the supporting plate 70, a plurality of bosses 64 and a plurality of narrowing pieces 65 are provided. When the back panel 60 is attached, the bosses 64 press the connecting component 50 against the supporting plate 70. Moreover, the narrowing pieces 65 abut the grasped pieces 55, narrowing the sliding of the connecting component 50 in a release direction R. This prevents the engagement of the engaging section 58 with the engaged section 28 from being released.

Incidentally, an operator can remove the connecting component 50 by releasing the engagement between the engaged section 28 and the engaging section 58 by sliding the connecting component 50 in a release direction R while grasping the grasped pieces 55 in a state in which the back panel 60 is removed. As described above, the connecting component 50 can be removed easily.

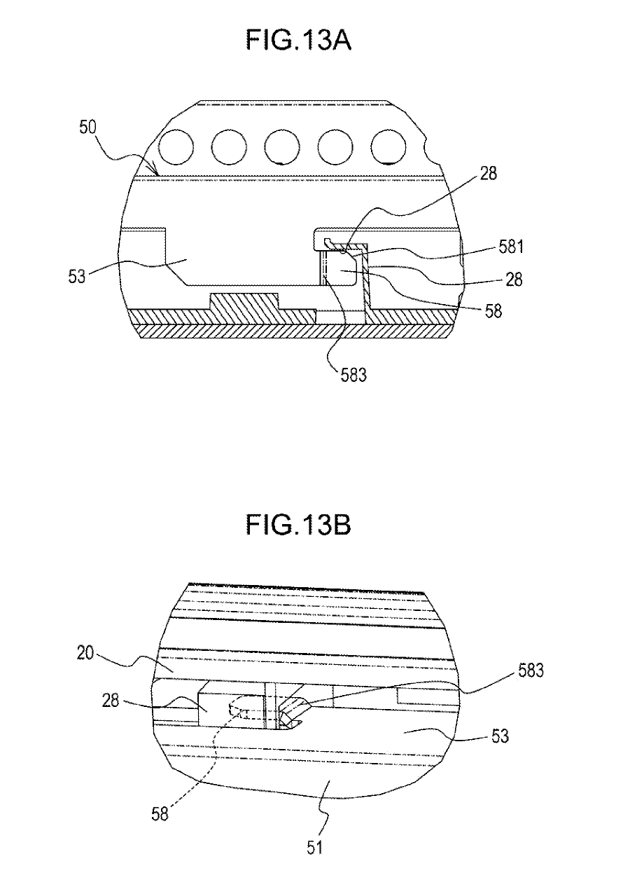

The engagement between the engaging section 58 and the engaged section 28 will be described. FIGS. 13A and 13B are diagrams showing the engagement between the engaging section 58 and the engaged section 28. As shown in FIG. 13A, the engaging section 58 has, at the tip thereof, a cut section 581 for making the engagement with the engaged section 28 easy. The cut section 581 is inclined to a direction in which the engaging section 58 extends. As shown in FIG. 13B, a bended section 583 located at the boundary between the limb section 53 and the engaging section 58 brings the engaging section 58 closer to the inside of the frame 20 than the limb section 53. This ensures the engagement between the engaging section 58 and the engaged section 28.

Moreover, as shown in FIG. 13A, when the engaging section 58 engages the engaged section 28, the position of the engaged section 28 in a direction of a depth of the display unit 30 is defined. This prevents the frame 20 from rising upward toward the front side of the display unit 30. The frame 20 is made of synthetic resin. Therefore, the frame 20 may suffer distortion due to a shape forming problem. When the frame 20 is distorted, a part of the frame 20 may rise upward from the display unit 30. However, the engagement between the engaged section 28 and the engaging section 58 prevents a part of the frame 20 from rising upward.

Furthermore, in a state in which the engaged section 28 and the engaging section 58 engage, repulsive force of the frame 20 acts between the engaged section 28 and the engaging section 58. That is, the engaged section 28 and the engaging section 58 engage in a state in which the frame 20 is forced to lie along the edge of the display unit 30. Since the frame 20 is made of synthetic resin and therefore can be elastically deformed to some extent, such repulsive force is generated in the frame 20.

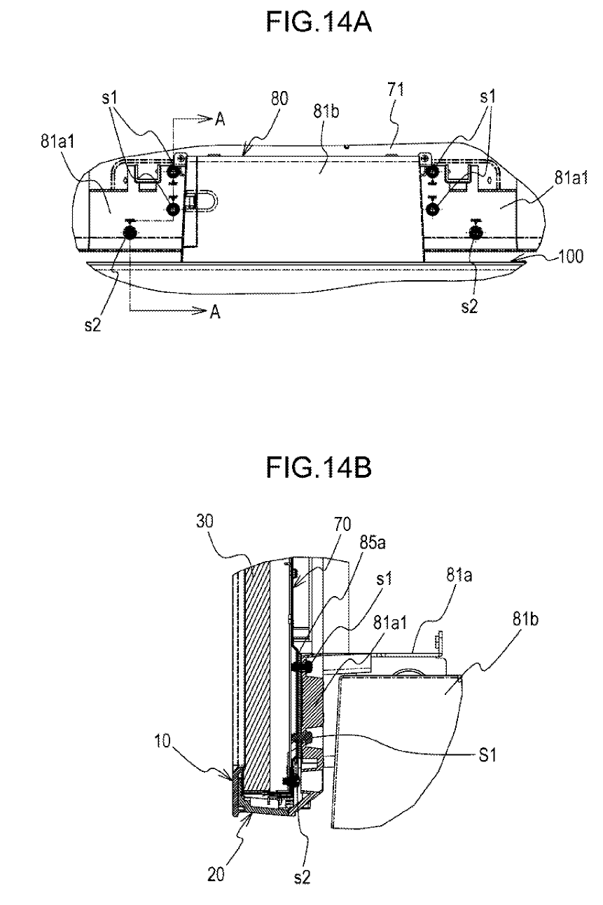

Next, maintenance will be described. FIG. 14A is a diagram showing a back face side of the pedestal section 80. FIG. 14B is a sectional view taken on the line A-A of FIG. 14A. As shown in FIG. 14B, the pedestal section 80 includes cases 81a and 81b. The movable body 83a and the fixed body 83b are disposed in the cases 81a and 81b. Moreover, tilting panels 81a1 covering the holding pieces 85a are formed integrally with the case 81a. The tilting panels 81a1 and the holding pieces 85a are both fixed to the supporting plate 70 with screws s1. Furthermore, the tilting panels 81a1 and the supporting plate 70 are fixed with screws s2. As shown in FIG. 14A, the screws s1 and s2 can be accessed from the back face side of the display apparatus 1.

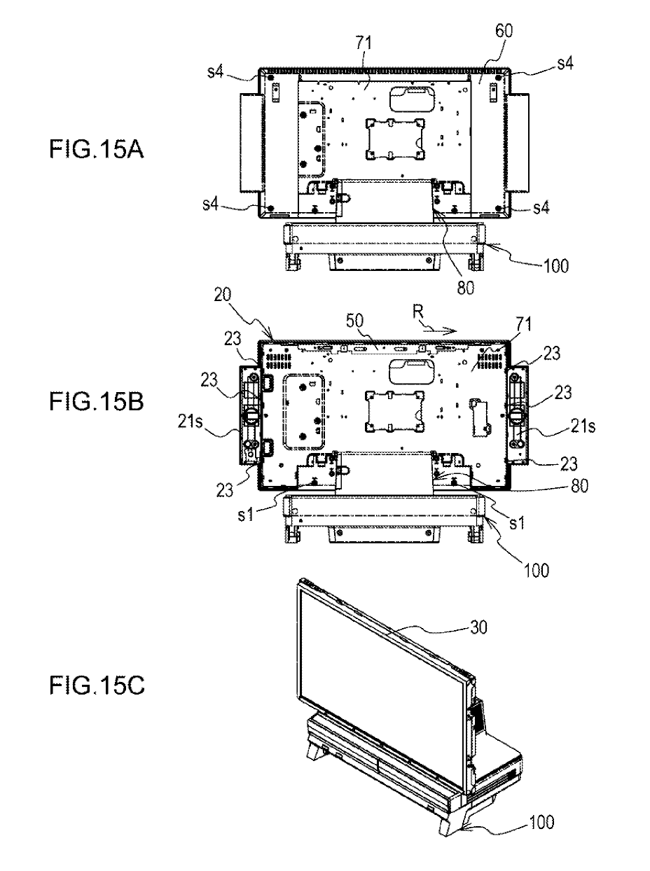

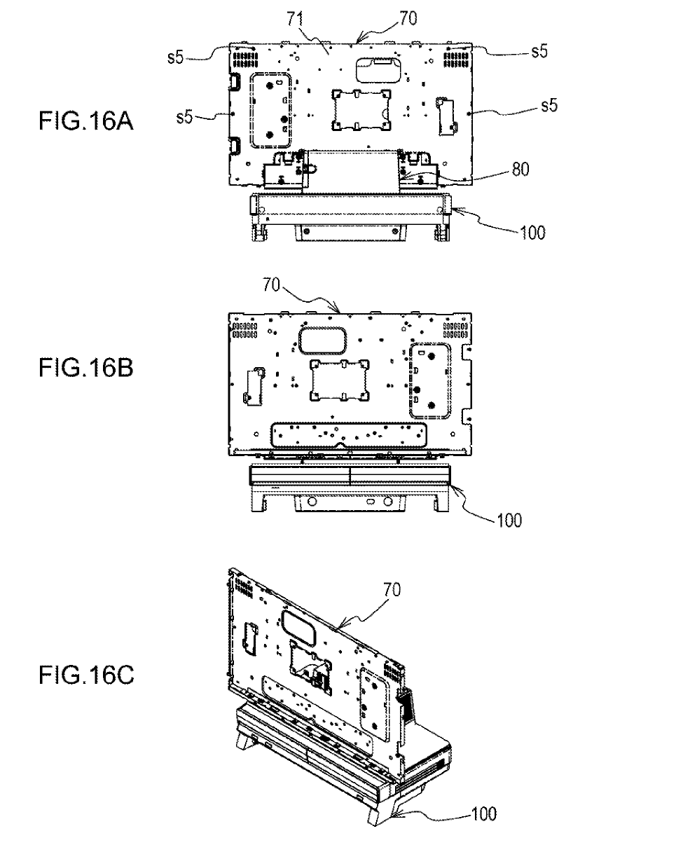

FIGS. 15A, 15B and 15C and FIGS. 16A, 16B and 16C are explanatory diagrams of maintenance. As shown in FIG. 15A, the operator removes the back panel 60 by unscrewing screws s4 with which the back panel 60 and the supporting plate 70 are fixed. Next, as shown in FIG. 15B, the operator removes the connecting component 50 by sliding the connecting component 50 in a release direction R, and unscrews the screws s1. Then, the operator removes a cable of a substrate disposed on the frame 20 and the brackets 40L and 40R. Next, the operator removes the front panel 10 and the frame 20 toward the front side of the display apparatus 1 while removing the locking pieces 23 from the supporting plate 70. FIG. 15C shows the display apparatus 1 in a state in which the frame 20 is removed therefrom. In this state, the display unit 30 is held by the supporting plate 70. In this way, it is possible to remove the front panel 10 and the frame 20 in a state in which the display unit 30 is held by the supporting plate 70.

Next, as shown in FIG. 16A, the operator unscrews screws s5 with which the display unit 30, the brackets 40L and 40R, and the supporting plate 70 are fixed, and removes the display unit 30 from the front side. FIGS. 16B and 16C are a front view and a perspective view, respectively, of the display apparatus 1 in a state in which the display unit 30 is removed therefrom.

As described above, the operator can remove (adjust) the display unit 30 with simple operation. This makes it possible to perform maintenance of the display unit 30 easily.

Although a preferred embodiment of the present invention has been described in detail, the present invention is not limited to such a specific embodiment, and many modifications and variations are possible within the scope of the subject matter of the present invention recited in the claims.

For example, the display apparatus 1 may be a device with an image display function alone, or may be a device, such as a personal computer, with an integrated information processing function.

The embodiments can be implemented to as a process of manufacture using a computing hardware (computing apparatus) and/or software, such as (in a non-limiting example) any computer that can store, retrieve, process and/or output data and/or communicate with other computers. The results produced can be displayed on a display of the computing hardware. A program/software implementing the embodiments may be recorded on computer-readable media comprising computer-readable recording media. The program/software implementing the embodiments may also be transmitted over transmission communication media. Examples of the computer-readable recording media include a magnetic recording apparatus, an optical disk, a magneto-optical disk, and/or a semiconductor memory (for example, RAM, ROM, etc.). Examples of the magnetic recording apparatus include a hard disk device (HDD), a flexible disk (FD), and a magnetic tape (MT). Examples of the optical disk include a DVD (Digital Versatile Disc), a DVD-RAM, a CD-ROM (Compact Disc-Read Only Memory), and a CD-R (Recordable)/RW. An example of communication media includes a carrier-wave signal.

Further, according to an aspect of the embodiments, any combinations of the described features, functions and/or operations can be provided.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention, the scope of which is defined in the claims and their equivalents.

What is claimed is:

1. A display apparatus comprising:
a display unit;
a frame that covers a side part of the display unit;
a supporting plate disposed on a back face side of the display unit; and
a connecting component that connects the frame and the supporting plate,
wherein the frame includes an engaged section provided inside the frame, and the connecting component includes:
a base section located in a position closer to the back face side of the display unit than the supporting plate;
a limb section that extends from the base section into a space between the side part of the display unit and the frame; and
an engaging section that extends from the limb section and defines a position of the frame in a direction of a depth of the display unit by engaging the engaged section.

2. The display apparatus according to claim 1, wherein a repulsive force of the frame acts between the engaging section and the engaged section in a state in which the engaging section and the engaged section engage.

3. The display apparatus according to claim 1, wherein the engaging section and the engaged section engage, or engagement between the engaging section and the engaged section is released when the connecting component is slid in a direction along one side of the display unit.

4. The display apparatus according to claim 3, wherein the supporting plate and the connecting component each include a sliding guiding section that guides sliding of the connecting component.

5. The display apparatus according to claim 3, comprising:
a back plate disposed on a back face side of the supporting plate, and
wherein the back plate and the connecting component each include a sliding narrowing section that narrows sliding of the connecting component, and the sliding narrowing section narrows release of the engagement between the engaging section and the engaged section.

6. The display apparatus according to claim 1, wherein the engaging section includes a cut section obliquely cut at a tip thereof.

7. The display apparatus according to claim 1, wherein the engaging section is closer to an inner face of the frame than the limb section.

8. The display apparatus according to claim 1, wherein the connecting component includes a holding component that is substantially U-shaped in cross section, the holding component is disposed along one side of the display unit and fixed to the frame in such a way as to surround an opposite side of the display unit, and the opposite side faces the one side of the display unit.

9. The display apparatus according to claim 1, comprising:
a positioning component fixed on the back face side of the display unit,
wherein one of the frame and the positioning component includes a convex section projecting in a planar direction of the display unit, and
the other of the frame and the positioning component includes a concave section that receives the convex section inserted thereinto.

10. The display apparatus according to claim 1, wherein one of the frame and the supporting plate includes a convex section that projects in a planar direction of the display unit, and
the other of the frame and the supporting plate includes a concave section that receives the convex section inserted thereinto.

11. The display apparatus according to claim 9, wherein the concave section narrows movement of the convex section in a direction perpendicular to a direction in which the convex section projects and allows the convex section to move in the direction in which the convex section projects.

12. The display apparatus according to claim 9, wherein the frame includes a positioning guiding section that guides the convex section into the concave section.

13. A display apparatus, comprising:
a display unit;
a frame that covers a side face of the display unit; and
a positioning component fixed on a back face side of the display unit, and
wherein one of the frame and the positioning component includes a convex section that projects in a planar direction of the display unit, and
the other of the frame and the positioning component includes a concave section that receives the convex section inserted thereinto.

14. A display apparatus, comprising:
a connector that connects a frame of a displayer;
an engager provided inside the frame; and
a limb section that extends from a base section supporting the displayer, wherein the engager is used to adjust a position of the frame in a perpendicular direction.
